(19) United States
(12) Patent Application Publication
(10) Pub. No.: US 2018/0090341 A1
(43) Pub. Date: Mar. 29, 2018

(54) SUBSTRATE TREATING METHOD AND SUBSTRATE TREATING DEVICE

(71) Applicant: SCREEN Holdings Co., Ltd., Kyoto (JP)

(72) Inventor: Yuji YAMAGUCHI, Kyoto (JP)

(21) Appl. No.: 15/710,160

(22) Filed: Sep. 20, 2017

(30) Foreign Application Priority Data
Sep. 26, 2016 (JP) 2016-186708

(51) Int. Cl. H01L 21/67; H01L 21/306; H01L 21/02; B08B 3/08; B08B 3/10

(52) U.S. Cl. CPC H01L 21/67023; H01L 21/30604; B08B 3/10; B08B 3/08; H01L 21/02057

(57) ABSTRACT

A substrate treating method is for etching and washing a predetermined substrate. Specifically, the substrate treating method includes: an etching step of dissolving a silicon film provided on a substrate, by using an alkaline etching liquid of which temperature is higher than a normal temperature; and a washing step of washing the substrate after the etching step, by using warm water of which temperature is higher than the normal temperature.

### CROSS-REFERENCE TO RELATED APPLICATION

This application is based upon and claims the benefit of priority of the prior Japanese Patent Application No. 2016-186708, filed on Sep. 26, 2016 the entire contents of which are incorporated herein by reference.

### BACKGROUND

### Technical Field

The present invention relates to a substrate treating method and a substrate treating device for performing an etching treatment and a washing treatment on a substrate of a semiconductor wafer and a relevant item.

A manufacturing process of a semiconductor device includes a step of performing an etching treatment and a washing treatment on a substrate of a semiconductor wafer and a relevant item, by immersing the substrate into a treating tank, and a step of performing a drying treatment of removing a treating liquid. Such steps are performed by a substrate treating device that includes a plurality of treating tanks. In the etching treatment and the washing treatment, a treating liquid suitable for a substance of an object to be dissolved is used. For example, there are proposed methods of washing the substrate, such as wet etching using hydrofluoric acid, rinse (washing) using pure water, drying, alkaline cleaning, and rinse using pure water (for example, JP 2013-84723 A).

Further, there is also proposed a method of forming a capacitor structure by etching a polycrystalline silicon film or an amorphous silicon film with an alkaline chemical liquid (for example, JP 5869368 B2).

In recent years, there has been a tendency that an etching quantity increases in the etching of a semiconductor substrate. Along with this increase in the etching quantity, there has arisen a problem that the etched component is recrystallized at the water washing time, for example.

### SUMMARY

Therefore, an object of the present invention is to suppress recrystallization of a substance dissolved in an etching liquid when etching and washing are performed on a substrate.

In order to solve the above, problem, the present invention has the following configuration.

The present invention provides a substrate treating method for performing etching and washing on a predetermined substrate. The substrate treating method includes: an etching step of dissolving a silicon film provided on the substrate, by using an alkaline etching liquid of which temperature is higher than a normal temperature; and a washing step of washing the substrate after the etching step, by using warm water of which temperature is higher than the normal temperature.

With this arrangement, because the substrate after the etching step is washed by using warm water of which temperature is higher than the normal temperature, an etching liquid adhering to the substrate is not rapidly cooled. Therefore, silicon of which solubility has exceeded the solubility of the etching liquid can be suppressed from being precipitated on the substrate surface.

The substrate treating method may further include a second washing step of washing the substrate by using a washing liquid that contains the same component as that of a diluted etching liquid. By using a washing liquid that contains the same component as that of the etching liquid, the effect of washing can be enhanced.

The washing liquid may further contain hydrogen peroxide water. With this arrangement, the etching treatment can be prevented from being performed using the washing liquid.

Also in the washing step, or in addition to the washing step, the substrate may be washed by spraying the warm water to the substrate. With this arrangement, the quantity of warm water used for washing can be reduced.

The substrate treating method may further include a transfer step of transferring the substrate to a treating tank for performing the washing step from the treating tank for performing the etching step. In the transfer step, the substrate may be warmed. With this arrangement, it is possible to suppress cooling the etching liquid adhering to the substrate in the transfer step and suppress precipitation of silicon associated with the cooling.

Further, a substrate treating device according to the present invention is a substrate treating device that performs etching and washing on a predetermined substrate. The substrate treating device includes an etching treating tank for dissolving a silicon film provided on a substrate, by using an alkaline etching liquid of which temperature is higher than a normal temperature; a washing treating tank for washing the substrate treated in the etching treating tank by using warm water of which temperature is higher than the normal temperature; and a temperature adjusting unit that generates the warm water by warming.

Means for solving the above problem can be used by appropriately combining together.

According to the present invention, when etching and washing are performed on a substrate, recrystallization of a substance dissolved in an etching liquid can be suppressed.

### BRIEF DESCRIPTION OF THE DRAWINGS

FIG. 1 is a perspective view showing a schematic configuration of a substrate treating device;

FIG. 2 shows a functional block diagram of the substrate treating device;

FIG. 3 is a view showing a configuration of a treating tank in a treating unit of the substrate treating device;

FIG. 4 is a schematic view showing steps of a washing treatment;

FIG. 5 is a schematic view showing steps of a washing treatment according to a first modification;

FIG. 6 is a schematic view showing an example of steps according to a second modification;

FIG. 7 is a schematic view showing an example of steps according to a fifth modification; and

FIG. 8 is a schematic view showing an example of steps according to a sixth modification.

### DETAILED DESCRIPTION

Embodiments of the present invention will be described in detail below with reference to the drawings. The embodiments described below represent one mode of the invention of the present application, and do not limit the technical range of the invention of the present application.

### First Embodiment

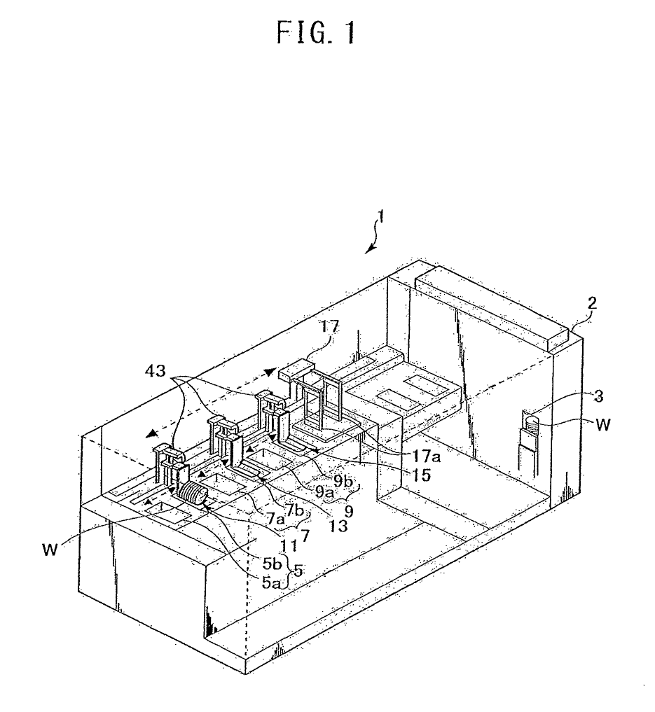

FIG. 1 is a perspective view showing a schematic configuration of a substrate treating device 1 according to a first embodiment. The substrate treating device 1 performs an etching treatment and a washing treatment on mainly a substrate (for example, a semiconductor substrate) W. In the substrate treating device 1, a buffer section 2 that stocks the substrate W is disposed on a right depth side in FIG. 1. On a further right depth side of the buffer section 2, a front panel (not shown) for operating the substrate treating device 1 is provided. Further, on an opposite side of the front panel of the buffer section 2, a substrate carry-out port 3 is provided. Further, treating units 5, 7, and 9 that perform a treatment on the substrate W are arranged in parallel from an opposite side of the buffer section 2 (a left front side in FIG. 1) in a longitudinal direction of the substrate treating device 1.

The treating units 5, 7, and 9 have two treating tanks 5a and 5b, two treating tanks 7a and 7b, and two treating tanks 9a and 9b, respectively. The treating tanks 5a, 7a, and 9a are etching treating tanks for performing the etching treatment, and the treating tanks 5b, 7b, and 9b are washing treating tanks for performing a washing treatment. The washing treatment is a rinse treatment (also referred to as “rinse”) for washing out an etching liquid remaining on the substrate W, with pure water or a diluted etching liquid. The substrate treating device 1 also includes sub-conveying mechanisms 43 that move a plurality of substrates W, in a direction and in a range indicated by a short arrow in FIG. 1, between treating tanks 5a and 5b, between treating tanks 7a and 7b, and between treating tanks 9a and 9b respectively included in the treating units 5, 7, and 9. The sub-conveying mechanisms 43 also vertically move the plurality of substrates W in order to immerse the plurality of substrates W into the treating tanks 5a and 5b, 7a and 7b, and 9a and 9b, or lift the substrates W from the treating tanks 5a and 5b, 7a and 7b, and 9a and 9b. The sub-conveying mechanisms 43 respectively include lifters 11, 13, and 15 for holding the plurality of substrates W. Further, the substrate treating device 1 includes a main conveying mechanism 17 which is movable in a direction and in a range indicated by a long arrow in FIG. 1, in order to convey the plurality of substrates W to each of the treating units 5, 7, and 9.

The main conveying mechanism 17 has two movable arms 17a. The arms 17a have a plurality of grooves (not shown) on which the substrates W are placed. The arms 17a hold, in the state shown in FIG. 1, substrates W in a standing posture (a posture in which the normal line of a substrate main surface is laid along the horizontal direction). The two arms 17a of the main conveying mechanism 17 swing in an upside-down shape of a character “V” when viewed from a right diagonally lower direction in FIG. 1, thereby releasing each substrate W. With the above operation, each substrate W can be delivered between the main conveying mechanism 17 and the lifters 11, 13, and 15.

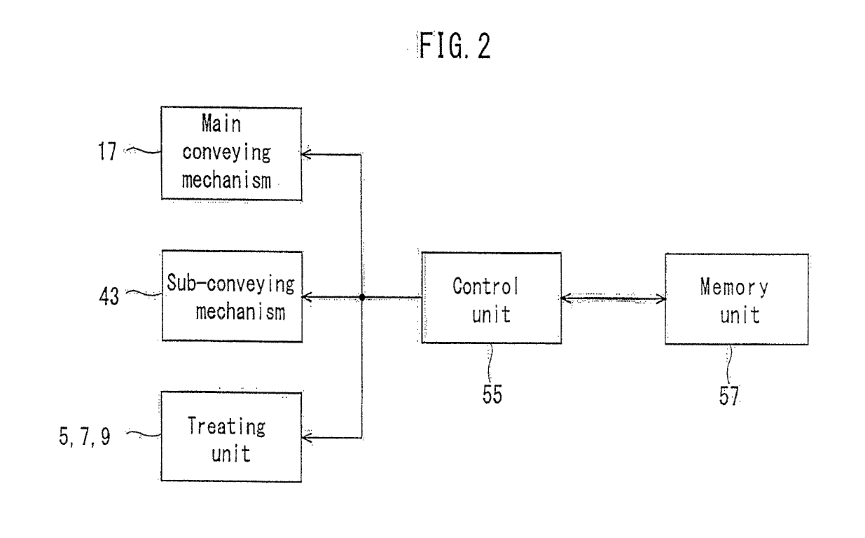

FIG. 2 shows a functional block diagram of the substrate treating device 1. The main conveying mechanism 17, the sub-conveying mechanisms 43, and the treating units 5, 7, and 9 are integrally controlled by a control unit 55. The configuration of the control unit 55 as hardware is similar to the configuration of a general computer. That is, the control unit 55 includes, for example, a CPU that performs various arithmetic processing, a ROM which is a read-only memory that stores a basic program, a RAM which is a writable and readable memory that stores various information items, and a magnetic disc that stores control application and data. In the present embodiment, the CPU of the control unit 55 controls each unit such that each unit executes a predetermined program to convey the substrates W to the treating units 5, 7, and 9 and each unit performs a treatment in accordance with the program. The program is stored in a memory unit 57. The memory unit 57 holds in advance parameters that become a standard for the program to operate, such as a time for continuing each treatment to be described later.

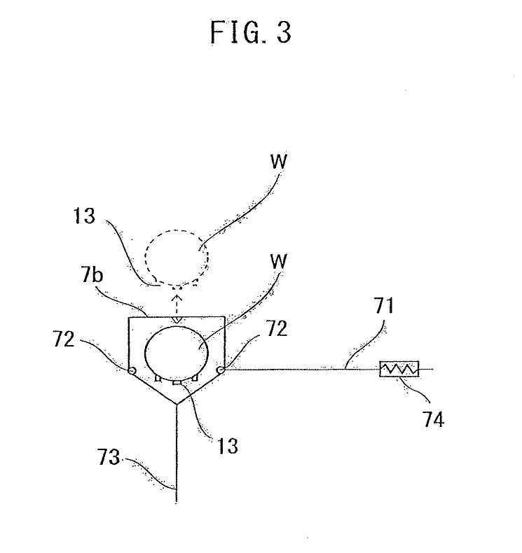

FIG. 3 is a view showing configurations of the treating tanks 5b, 7b, and 9b respectively included in the treating units 5, 7, and 9 of the substrate treating device 1. With reference to FIG. 3, a description will be made by taking the treating tank 7b as an example. A configuration and a control equivalent to or similar to the configuration and the control of the treating tank 7b are also applied to the other treating tanks 5b and 9b.

In a manufacturing process of a semiconductor wafer, a monocrystalline ingot of silicon, for example, is sliced in a rod axis direction of the ingot. The sliced wafers are sequentially subjected to chamfering, lapping, an etching treatment, a polishing treatment, and the like. As a result, a plurality of layers, structures, and circuits made of different materials are formed on the substrate surface. The etching treatment of the substrate W performed in the treating tank 7a is a process for forming a pattern on the semiconductor substrate, for example. The etching treatment is performed for the purpose of selectively removing a silicon film (Si film) formed on the substrate, and is performed by immersing the substrate W for a predetermined time into a high-temperature (about 80° C.)-alkaline etching liquid which is a treating liquid.

In FIG. 3, the treating tank 7b is a box-shaped member formed in a rectangular shape in a plan view and formed of a quartz or fluororesin material excellent in corrosion resistance against the treating liquid. The treating tank 7b may have a double-tank structure (not shown) configured by an inner tank in which the substrate W is immersed into the treating liquid, and an outer tank which is provided around the inner tank and into which the treating liquid that overflows from the upper end of the inner tank flows. Further, the treating tank 7b has a supply pipe 71 and a nozzle 72 for supplying a treating liquid (also referred to as a “washing liquid”) for washing the substrate (4, a discharge pipe 73 for discharging the washing liquid from the treating tank 7b, and a temperature adjuster (corresponding to the “temperature adjusting unit” according to the present invention) 74 such as a heater that warms the treating liquid supplied from the supply pipe 71. The supply pipe 71 and the discharge pipe 73 each have a valve (not shown), and the control unit 55 (FIG. 2) controls supply and discharge of the washing liquid. The washing liquid may be discharged by overflowing from an opened upper end of the treating tank 7b. Further, the washing liquid discharged from the discharge pipe 73 may be filtered and circulated again to the supply pipe 71.

The treating tank 7b is also provided with a lifter 13 for immersing the substrate W into the treating liquid stored as described above. The lifter 13 collectively holds, with three holding rods, a plurality of (for example, 50) substrates W that are arranged in parallel with each other in a standing posture. The lifter 13 is provided movably in vertical and lateral directions by the sub-conveying mechanisms 43. The lifter 13 can be moved up and down between a treatment position (a solid line in FIG. 3) at which a plurality of the substrates W being held are immersed into the treating liquid in the treating tank 7b and a delivery position (a broken line in FIG. 3) at which the plurality of the substrates W are lifted upward from the treating liquid. The lifter 13 can be also moved to the adjacent treating tank.

### (Treatment)

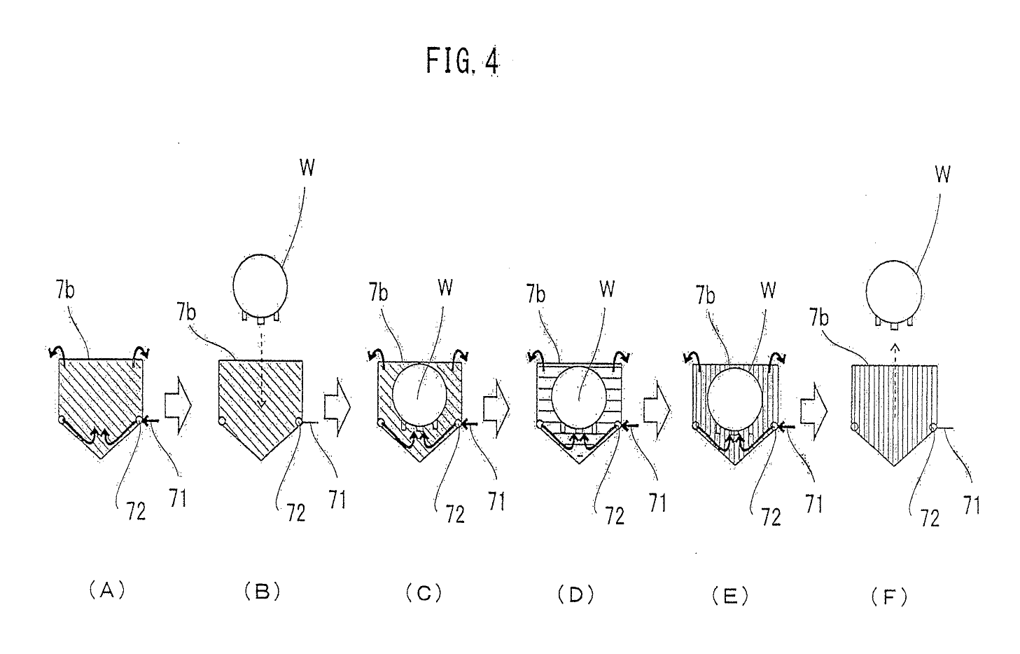

FIG. 4 is a schematic view showing steps of the washing treatment in the treating tank 7b in the present embodiment. Prior to performing the step shown in FIG. 4, there is performed the etching step of etching a silicon (Si) film of the substrate W by using an alkaline chemical liquid (also referred to as an “etching liquid”) in the treating tank 7a. The silicon′ film is a thin film formed of a material such as amorphous silicon and polysilicon. The alkaline etching liquid is, for example, an aqueous solution containing trimethyl-2-hydroxyethyl ammonium hydroxide (THY) or tetramethylammonium hydroxide (TMAH), or ammonium hydroxide (ammonia water).

Thereafter, in the state that the etching liquid adheres to the surface of the substrate W, the substrate W is transferred to the treating tank 7b, and the washing treatment shown in FIG. 4 is performed. In this case, when the treatment of a large etching quantity is performed as compared with a conventional practice, like the formation of a three-dimensional NAND, for example, supersaturated silicon is precipitated out of the etching liquid adhering to the substrate W, and the precipitated silicon remains as a particle on the substrate W after drying. In order to suppress this remaining, washing is performed with warm water in the present embodiment.

In (A) of FIG. 4, warm water supplied from the supply pipe 71 is supplied from the nozzle 72 to the treating tank 7b. In FIG. 4, the flow of a liquid is indicated by a solid line arrow. The warm water is pure water at a higher temperature than the normal temperature. Specifically, pure water at around 50 to 80° C. is used. In (A) of FIG. 4, the warm water may be filled into the treating tank 7b which is empty. The warm water may be filled into the treating tank 7b in the state of replacing the washing liquid that is remaining after the washing liquid is used in the preceding treatment. The normal temperature indicates that a positive temperature adjustment is not performed. Actually, the normal temperature is around 24° C. to 26° C.

In (B) of FIG. 4, the lifter 13 on which the substrate W is placed is moved to a treatment position by the sub-conveying mechanisms 43, and the substrate W is immersed into the warm water in the treating tank 7b.

Then, as shown in (C) of FIG. 4, in the state that the substrate W is immersed into the warm water, the warm water in the treating tank 7b is replaced, and the substrate W is washed. As shown in FIG. 4, a sectional shape of the treating tank 7b is in a baseball home base shape which is protruded to a vertical downward direction. The nozzle 72 is provided on a lower part of the treating tank 7b on left and right side surfaces. From the nozzle 72, newly supplied warm water is discharged toward a lower end in a protruded shape on the bottom surface of the treating tank 7b. Then, the warm water discharged from the left and right nozzles collide at the center of the bottom surface of the treating tank 7b, and rises in the treating tank 7b. At this time, the warm water on the surface of the substrate W held at the treatment position is replaced, and a part of the warm water overflows from the upper end of the treating tank 7b so that the warm water is discharged. For example, the treatment of (C) lasts for about five minutes. The step of (C) corresponds to the washing step according to the present invention.

Thereafter, in (D) of FIG. 4, the washing liquid supplied from the supply pipe 71 is replaced with a mixed liquid of warm water and an alkaline etching liquid. In other words, the mixed liquid is a diluted etching liquid, and will be also referred to as a “warm washing liquid”. The temperature of the warm washing liquid is higher than the normal temperature, and the warm washing liquid of about 50 to 80° C. is used. By washing the substrate W with the warm washing liquid containing the same component as that of the etching liquid, the washing effect can be enhanced, and adhesion of foreign matters to the substrate W can be suppressed. The warm washing liquid may further be a mixed liquid containing hydrogen peroxide water (H₂O₂). By using such a mixed liquid, an excessive etching treatment by the warm washing liquid can be suppressed. The step of (D) of FIG. 4 corresponds to the second washing step according to the present invention.

In (E) of FIG. 4, the washing liquid supplied from the supply pipe 71 is replaced with water of the normal temperature (also referred to as “cold water” to distinguish from warm water). In the present step, the substrate W can be cooled and washed at the same time.

Thereafter, as shown in (F) of FIG. 4, the washing is completed, and the substrate W is discharged from the treating tank 7b by moving the lifter 13.

### (Effects)

According to the present embodiment, recrystallization of silicon from the etching liquid adhering to the substrate W can be suppressed, by using warm water for the washing. That is, when the etching liquid is rapidly cooled by washing with pure water of the normal temperature in the washing step, the silicon is estimated to be precipitated because the solubility of silicon that can be dissolved in the etching liquid becomes low. In order to avoid this, in the present embodiment, the steps of (A) to (D) of FIG. 4 are added. When the etching treatment performed before the washing treatment according to the present embodiment is the etching treatment performed by immersing the substrate W into a predetermined quantity of the etching liquid that does not circulate, or is the etching treatment performed by circulating a predetermined quantity of the etching liquid in a closed system without replacement, there is a high possibility that the concentration of the silicon exceeds a saturated concentration during cooling. Therefore, washing with warm water is particularly useful.

### Second Embodiment

In the first embodiment, the step shown in (D) of FIG. 4 may be omitted. That is in a second embodiment, the treatments shown in (A) to (C), (E) and (F) of FIG. 4 are performed. In the present embodiment, in the step of (C), by increasing the replacement quantity of warm water per hour, adhesion of foreign matters can be suppressed even when the step of (D) is omitted. For example, for the treating tank 7b of which the capacity is 35 liters, it is preferable to replace the warm water of 50 liters every minute in the step of (C).

### <First Modification>

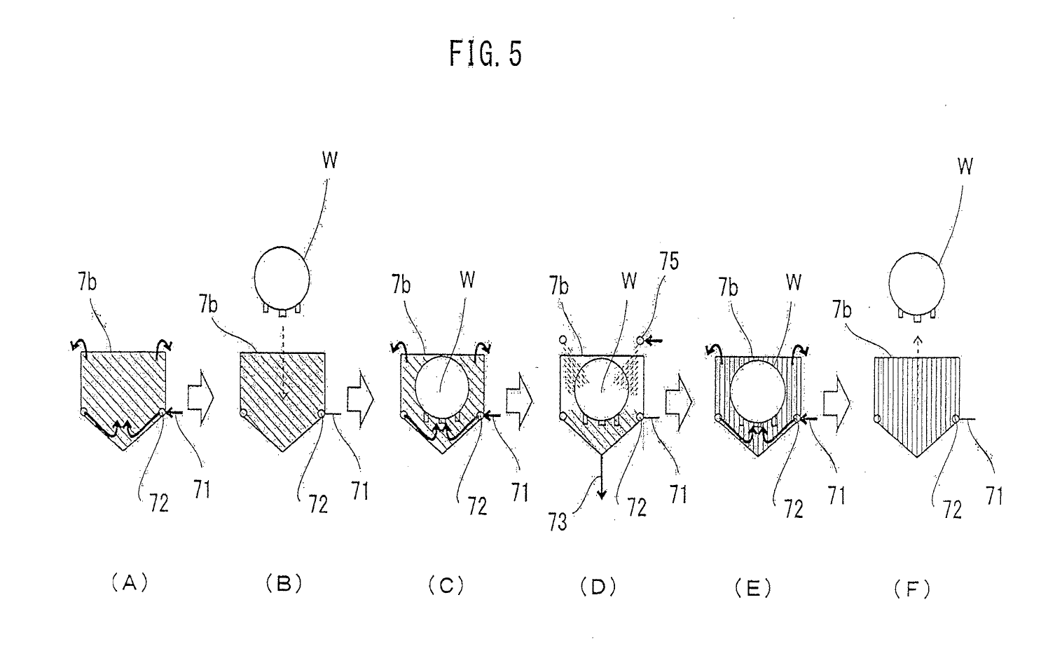

FIG. 5 is a schematic view showing steps of a washing treatment according to a first modification. The treating tank 7b according to the first modification has, at its upper part, a shower nozzle 75 for spraying warm water widely in the treating tank 7b. Warm water can be sprayed from above the substrate W which is held at a treatment position in the treating tank 7b.

In (A) of FIG. 5, warm water is filled in the treating tank 7b. In (B) of FIG. 5, the substrate W is moved into the treating tank 7b. Then, in (C) of FIG. 5, the substrate W is washed while the warm water in the treating tank 7b is replaced. Because the steps shown in (A) to (C) of FIG. 5 are similar to the steps of (A) to (C) of FIG. 4, a detailed description will be omitted.

In (D) of FIG. 5, warm water in the treating tank 7b is discharged from the discharge pipe 73, and at the same time, the warm water is sprayed from the shower nozzle 75 to the substrate W, and the substrate W is washed. The temperature of the warm water to be sprayed ranges from about 50 to 80° C., for example.

Thereafter, as shown in (E) of FIG. 5, the spray of warm water from the shower nozzle 75 is stopped, and at the same time, water of the normal temperature is supplied from the nozzle 72, and the substrate W is washed with cold water. As shown in (F) of FIG. 5, the washing is completed, and the substrate W is discharged from the treating tank 7b. Because the steps shown in (E) and (F) of FIG. 5 are similar to the steps of (E) and (F) of FIG. 4, a detailed description will be omitted.

In the first modification, by adopting washing with shower, a washing efficiency can be improved, and at the same time, a total quantity of the washing liquid used for washing can be reduced.

### <Second Modification>

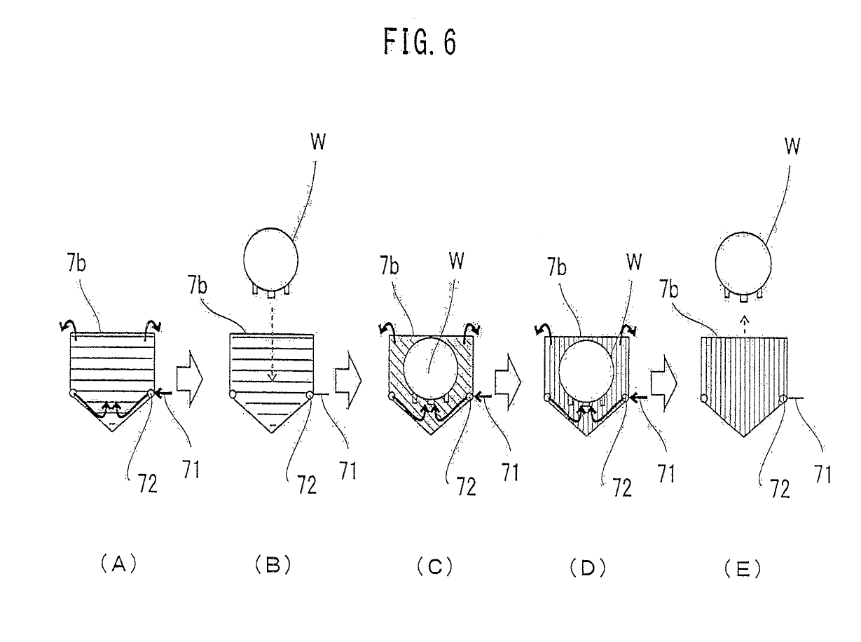

FIG. 6 is a schematic view showing an example of steps according to the second modification. Before entering the substrate W, the treating tank 7b may be filled with the warm washing liquid, not warm water. In (A) of FIG. 6, the warm washing liquid is filled into the treating tank 7b by supplying the warm washing liquid from the nozzle 72. As shown in (B) of FIG. 6, the substrate W is immersed into the treating tank 7b in which the warm washing liquid is filled. In the present step, the supply of the warm washing liquid is stopped, and the warm washing liquid is not circulated.

Thereafter, as shown in (C) of FIG. 6, warm water is supplied from the nozzle 72, and the washing liquid in the treating tank 7b is replaced with warm water and at the same time the substrate W is washed. Then, as shown in (D) of FIG. 6, by supplying cold water from the nozzle 72, the washing liquid in the treating tank 7b is replaced with the cold water, and the substrate W is washed and cooled at the same time. Thereafter, as shown in (E) of FIG. 6, the washing is completed, and the substrate W is discharged from the treating tank 7b. Because the steps shown in (C) to (E) of FIG. 6 are similar to the steps of (C), (E), and (F) of FIG. 4, a detailed description will be omitted.

The steps of (A) and (B) according to the second modification can be applied to the step of entering the substrate W in other embodiments or modifications. In these steps, by washing the substrate W with the warm washing liquid containing the same component as that of the etching liquid, the washing effect can be enhanced, and adhesion of foreign matters to the substrate W can be suppressed.

### <Third Modification>

At the time of entering the substrate W into the treating tank 7b, a high-temperature gas may be blown to the substrate W. For example, the treating tank 7b according to the present modification has, at its upper part, an air blower (not shown) for blowing a high-temperature gas to the substrate W. The gas is nitrogen (N₂), for example. The gas has a temperature of about 50 to 100° C., for example. The gas is blown not to dry the substrate W.

With this arrangement, in the step of transferring the substrate W between the treating tanks, cooling of the substrate W can be suppressed. As a result, precipitation of silicon out of the treating liquid adhering to the substrate W in the etching step can be suppressed.

### <Fourth Modification>

The filling of warm water or a warm washing liquid to the treating tank 7b may be realized by heating the liquid already filled in the treating tank 7b. The treating tank 7b according to the present modification may have a temperature adjusting device such as a heating light source like a halogen heater, for example, and the temperature adjusting device may heat the liquid. With this arrangement, time required for replacing the warm water or the warm water aqueous solution can be reduced.

### <Fifth Modification>

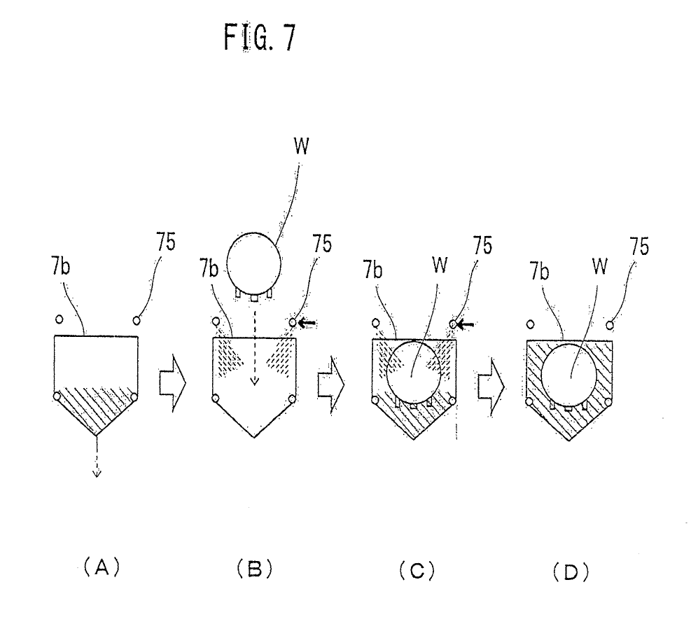

FIG. 7 is a schematic view showing an example of steps according to a fifth modification. The treating tank 7b according to the fifth modification has, at its upper part, the shower nozzle 75 for spraying warm water widely in the treating tank 7b. Warm water can be sprayed from above the substrate W which is held at a treatment position in the treating tank 7b. The shower nozzle 75 is similar to that in the first modification.

In the present modification, as shown in (A) of FIG. 7, the treatment is performed in the state that the liquid has been discharged and the treating tank 7b is not filled with the treating liquid. Further, as shown in (B) of FIG. 7, at the time of entering the substrate W into the treating tank 7b, warm water is sprayed from the shower nozzle 75 to the substrate W. With this arrangement, reduction in the temperature of the substrate W can be suppressed, and the washing effect can be improved. In (C) of FIG. 7, warm water is supplied from the nozzle 72 to the treating tank 7b to fill the treating tank 7b. At this time, warm water may or may not be sprayed from the shower nozzle 75. In (D) of FIG. 7, the substrate W is washed with warm water, and further, the washing treatment shown in (D) and after or in (E) and after of FIG. 4 is performed, for example.

### <Sixth Modification>

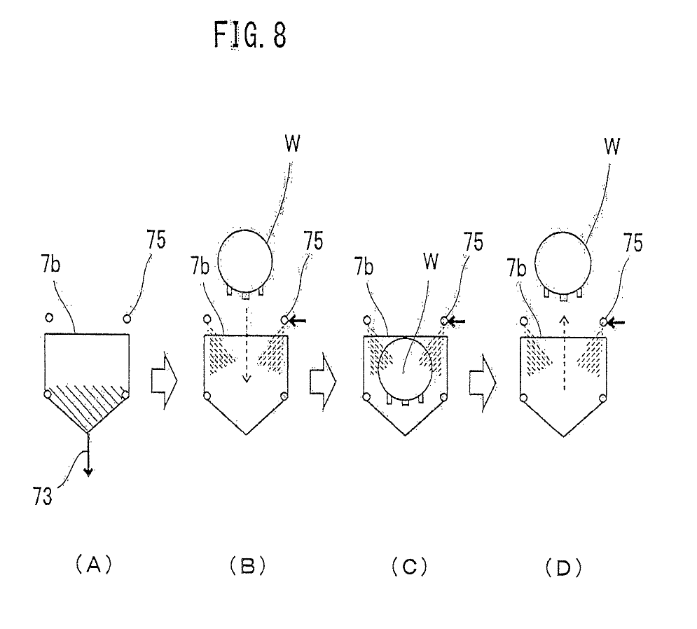

FIG. 8 is a schematic view showing an example of steps according to a sixth modification. The treating tank 7b according to the sixth modification has also, at its upper part, the shower nozzle 75 for spraying warm water widely in the treating tank 7b. Warm water can be sprayed from above the substrate W which is held at a treatment position in the treating tank 7b. The shower nozzle 75 is similar to that in the first modification.

In the present modification, warm water is sprayed from the shower nozzle 75 to perform washing. That is, as shown in (A) of FIG. 8, for example, the treatment is performed in the state that the liquid has been discharged and the treating tank 7b is not filled with the treating liquid. In (B) of FIG. 8, at the time of entering the substrate W into the treating tank 7b, warm water is sprayed from the shower nozzle 75 to the substrate W. With this arrangement, reduction in the temperature of the substrate W can be suppressed, and the washing effect can be improved. In (C) of FIG. 8, warm water is sprayed to the substrate W to perform washing. At this time, by vertically sliding the lifter 13 with the sub-conveying mechanism 43, warm water may be sufficiently delivered to the inside of the substrate W that has been etched. Thereafter, as shown in (D) of FIG. 8, the washing is completed, and the substrate W is discharged from the treating tank 7b. At this time, warm water is continued to be sprayed from the shower nozzle 75, for example.

As described in the sixth modification, when the washing is performed by only the shower of warm water, a total quantity of warm water used for the washing can be reduced.

### <Others>

The contents described in the embodiments and the modifications can be performed by combining together to an achievable extent.

What is claimed is:

1. A substrate treating method for performing etching and washing on a predetermined substrate, the substrate treating method comprising:
an etching step of dissolving a silicon film provided on the substrate, by using an alkaline etching liquid of which temperature is higher than a normal temperature; and
a washing step of washing the substrate after the etching step, by using warm water of which temperature is higher than the normal temperature.

2. The substrate treating method according to claim 1, further comprising a second washing step of washing the substrate by using a washing liquid that contains the same component as that of a diluted etching liquid.

3. The substrate treating method according to claim 2, wherein the washing liquid further contains hydrogen peroxide water.

4. The substrate treating method according to claim 1, wherein in the washing step, or in addition to the washing step, the substrate is washed by spraying the warm water to the substrate.

5. The substrate treating method according to claim 1, further comprising a transfer step of transferring the substrate to a treating tank for performing the washing step from the treating tank for performing the etching step,
wherein in the transfer step, the substrate is warmed.

6. A substrate treating device that performs etching and washing on a predetermined substrate, the substrate treating device comprising:
an etching treating tank for dissolving a silicon film provided on a substrate, by using an alkaline etching liquid of which temperature is higher than a normal temperature;
a washing treating tank for washing the substrate treated in the etching treating tank, by using warm water of which temperature is higher than the normal temperature; and
a temperature adjusting unit that generates the warm water by warming.
